(19) United States
(12) Patent Application Publication
(10) Pub. No.: US 2021/0295003 A1
(43) Pub. Date: Sep. 23, 2021

(54) ULTRASONIC MODULE, ULTRASONIC SENSOR AND DISPLAY SCREEN

(71) Applicant: BOE TECHNOLOGY GROUP CO., LTD., Beijing (CN)

(72) Inventors: Yingming LIU, Beijing (CN); Haisheng WANG, Beijing (CN); Xiaoliang DING, Beijing (CN); Lei WANG, Beijing (CN); Pengpeng WANG, Beijing (CN); Lijun ZHAO, Beijing (CN); Peixiao LI, Beijing (CN)

(21) Appl. No.: 17/256,065

(22) PCT Filed: Jun. 11, 2020
(86) PCT No.: PCT/CN2020/095536

§ 371 Date: Dec. 24, 2020

(30) Foreign Application Priority Data
Jun. 25, 2019 (CN) 201910554542.6

(51) Int. Cl. G06K 9/00; B06B 1/06; B06B 1/02

(52) U.S. Cl. CPC G06K 9/0002; B06B 1/0692; H01L 27/3234; B06B 2201/56; B06B 2201/70; B06B 1/0207

(57) ABSTRACT

The present disclosure provides an ultrasonic module, an ultrasonic sensor and a display screen, and belongs to a display technical field, and may at least partly solve the problem that the current ultrasonic module has a low conversion rate of the ultrasonic wave. The present disclosure discloses an ultrasonic module including: a piezoelectric material layer; a first electrode unit arranged at a side of the piezoelectric material layer; and a second electrode unit arranged on a side of the piezoelectric material layer distal to the first electrode unit, wherein the second electrode unit includes a plurality of first sub-electrode layers and a plurality of first conductive elastic material blocks arranged at intervals along a direction parallel to an extending direction of the piezoelectric material layer, the plurality of first conductive elastic material blocks are arranged between the plurality of first sub-electrode layers and the piezoelectric material layer, and each of the plurality of first sub-electrode layers corresponds to a corresponding one of the plurality of first conductive elastic material blocks.

### CROSS-REFERENCE TO RELATED APPLICATIONS

This application claims the priority to the Chinese Patent Application No. 201910554542.6, filed on Jun. 25, 2019, which is incorporated herein in its entirety by reference.

### TECHNICAL FIELD

The present disclosure relates to the field of display technology, and in particular to an ultrasonic module, an ultrasonic sensor and a display screen.

### BACKGROUND

As full-screen displays have got widespread attention, under-screen fingerprint identification technology has also got more and more attention. An under-screen fingerprint identification technology in the prior art uses ultrasonic fingerprint identification. Specifically, as shown in FIG. 1, an ultrasonic module includes a first electrode 11, a second electrode 12, and a piezoelectric material layer 13 located between the two electrodes. The working principle is as follows: a voltage between the first electrode 11 and the second electrode 12 is constantly changed, so that the piezoelectric material layer 13 is deformed to generate mechanical vibration, thereby emitting ultrasonic waves; when a finger or other things approaches or touches the display screen, ultrasonic waves reflected from the finger or other things are transmitted to the piezoelectric material layer 13, so that the piezoelectric material layer 13 generates a change of an electric signal, and feeds back the change of the electric signal to one of the electrodes, thereby achieving the identification.

However, the ultrasonic module of the prior art has low ultrasonic conversion rate and low ultrasonic utilization efficiency, thereby causing a problem of poor performance in identifying fingers or other things.

### SUMMARY

The present disclosure provides an ultrasonic module with a high conversion rate of the ultrasonic wave, which includes: a piezoelectric material layer; a first electrode unit arranged on a side of the piezoelectric material layer; a second electrode unit arranged on a side of the piezoelectric material layer distal to the first electrode unit, and the second electrode unit includes a plurality of first sub-electrode layers arranged at intervals along a direction parallel to an extending direction of the piezoelectric material layer and a plurality of first conductive elastic material blocks arranged at intervals along the direction parallel to the extending direction of the piezoelectric material layer; the plurality of first conductive elastic material blocks are arranged between the plurality of first sub-electrode layers and the piezoelectric material layer; each of the plurality of first sub-electrode layers corresponds to a corresponding one of the plurality of first conductive elastic material blocks.

In one embodiment, the plurality of first conductive elastic material blocks include a plurality of spherical first conductive elastic material blocks.

In one embodiment, the second electrode unit further includes a plurality of second sub-electrode layers between the plurality of first conductive elastic material blocks and the piezoelectric material layer; each of the plurality of first sub-electrode layers corresponds to a corresponding one of the plurality of second sub-electrode layers.

In one embodiment, orthographic projections of the plurality of first sub-electrode layers on the piezoelectric material layer and orthographic projections of the plurality of second sub-electrode layers on the piezoelectric material layer are overlapped, respectively.

In one embodiment, the first electrode unit includes a plurality of third sub-electrode layers arranged at intervals along the direction parallel to the extending direction of the piezoelectric material layer and a plurality of second conductive elastic material blocks arranged at intervals along the direction parallel to the extending direction of the piezoelectric material layer; the plurality of second conductive elastic material blocks are arranged between the plurality of third sub-electrode layers and the piezoelectric material layer; each of the third sub-electrode layers corresponds to a corresponding one of the plurality of second conductive elastic material blocks.

In one embodiment, the plurality of second conductive elastic material blocks includes a plurality of spherical second conductive elastic material blocks.

In one embodiment, the ultrasonic module is an ultrasonic fingerprint identification module.

The technical solution for solving the technical problem of the present disclosure further includes an ultrasonic sensor, which includes: the ultrasonic module described above, a first substrate; a second substrate aligned and assembled together with the first substrate; the ultrasonic module is arranged between the first substrate and the second substrate, the first substrate is arranged on a side of the first electrode unit distal to the second electrode unit, and the second substrate is arranged on a side of the second electrode unit distal to the first electrode unit.

In one embodiment, the ultrasonic module is the ultrasonic module described above, and the ultrasonic sensor further includes a plurality of supports arranged at intervals along the direction parallel to the extending direction of the piezoelectric material layer, and the plurality of supports are arranged between the second substrate and the piezoelectric material layer for supporting the second substrate and the piezoelectric material layer; and one first sub-electrode layer, one spherical first conductive elastic material and one second sub-electrode layer are arranged between two adjacent supports.

In one embodiment, the two adjacent supports together with the second substrate and the piezoelectric material layer form an independent enclosed chamber.

In one embodiment, the plurality of supports are made of a non-conductive and non-elastic material, and a cross section of each of the plurality of supports is circular or square.

In one embodiment, each first sub-electrode layer and the corresponding second sub-electrode layer correspond to one sub-pixel of the ultrasonic sensor.

In one embodiment, the second substrate is a driving substrate having pixel driving circuits.

In one embodiment, the first electrode unit is electrically coupled to the driving substrate through a conductive connector arranged between the first electrode unit and the second substrate.

In one embodiment, the conductive connector is made of a spherical conductive elastic material.

The present disclosure also provides a display screen, including: the above-mentioned ultrasonic sensor; a display device; wherein the display device is attached to the ultrasonic sensor.

In one embodiment, the display device includes a liquid crystal display panel or an Organic Light Emitting Diode (OLED) display panel.

### BRIEF DESCRIPTION OF THE DRAWINGS

FIG. 1 is a schematic structural view of a ultrasonic module in the prior art;

FIG. 2 is a schematic structural view of an ultrasonic module according to an embodiment of the present disclosure;

FIGS. 3a to 3c are schematic structural views illustrating an operating principle of an ultrasonic module according to an embodiment of the present disclosure;

FIG. 4 is a schematic structural view of a display screen according to an embodiment of the present disclosure; and

FIG. 5 is a schematic structural view of an ultrasonic module according to an embodiment of the present disclosure.

### DETAILED DESCRIPTION

In order that a person skilled in the art will better understand the technical solutions of the present disclosure, the following detailed description is given with reference to the accompanying drawings and the specific embodiments.

The present disclosure will be described in detail below with reference to the accompanying drawings. Same elements in the drawings are denoted by similar annotations. For purposes of clarity, the various elements in the drawings are not drawn to scale. Moreover, certain well-known elements may not be shown in the drawings.

Numerous specific details of the present disclosure, such as structures, materials, dimensions, treatment processes and technology, are set forth in the following description in order to provide a more thorough understanding of the present disclosure. However, as will be understood by a person skilled in the art, the present disclosure may be practiced without these specific details.

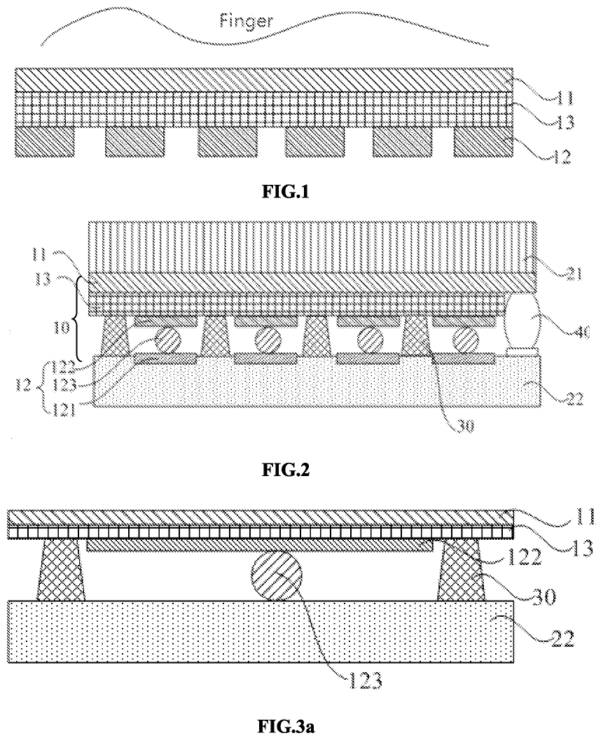

In one embodiment of the present disclosure, as shown in FIG. 2, the present embodiment provides an ultrasonic module 10, including: a piezoelectric material layer 13; a first electrode unit 11 arranged on a side of the piezoelectric material layer 13; a second electrode unit 12 arranged on a side of the piezoelectric material layer 13 distal to the first electrode unit 11, wherein the second electrode unit 12 includes a plurality of first sub-electrode layers 121 and a plurality of first conductive elastic material blocks 123 arranged at intervals along a direction parallel to an extending direction of the piezoelectric material layer 13, and the plurality of first conductive elastic material blocks 123 are arranged between the plurality of first sub-electrode layers 121 and the piezoelectric material layer 13; each of the plurality of first sub-electrode layers 121 corresponds to a corresponding one of the plurality of first conductive elastic material blocks 123.

The structure of the ultrasonic module 10 includes the first electrode unit 11, the piezoelectric material layer 13, the first conductive elastic material blocks 123 and the first sub-electrode layers 121 arranged sequentially. The piezoelectric material layer 13 may be a polyvinylidene fluoride (PVDF) film layer, or may be another inorganic or organic material layer such as aluminum nitride (AlN), lead zirconate titanate piezoelectric ceramics (PZT), or zinc oxide (ZnO). The first electrode unit 11 is an ultrasonic emission driving electrode; the first electrode unit 11 includes a driving electrode formed of a thin metal material such as Indium Tin Oxide (ITO), molybdenum (Mo), or the like. The second electrode unit 12 is an ultrasonic reception pixel electrode, and may be used as a fingerprint reception electrode.

It should be noted that the functions of the first electrode unit 11 and the second electrode unit 12 may be interchanged according to different settings, that is, the first electrode unit 11 may also be an ultrasonic reception pixel electrode; the second electrode unit 12 may also be an ultrasonic emission driving electrode.

The working principle of the ultrasonic module 10 is as follows: applying a voltage to the first electrode unit 11 and the second electrode unit 12 to generate an electric field, and the piezoelectric material layer 13 is in the electric field, and the piezoelectric material layer 13 is mechanically deformed under the electric field, so that ultrasonic waves are generated and transmitted to one side (such as a position of a finger or other external things) of the first electrode unit 11 or the second electrode unit 12; when the finger or other external things approach the first electrode unit 11 or the second electrode unit 12 of the ultrasonic module 10, the ultrasonic waves emitted by the piezoelectric material layer 13 are reflected back into the piezoelectric material layer 13 due to the finger or other external things, so that the piezoelectric material layer 13 is mechanically deformed again, which generates an electric signal, and the information is identified by determining the electric signal.

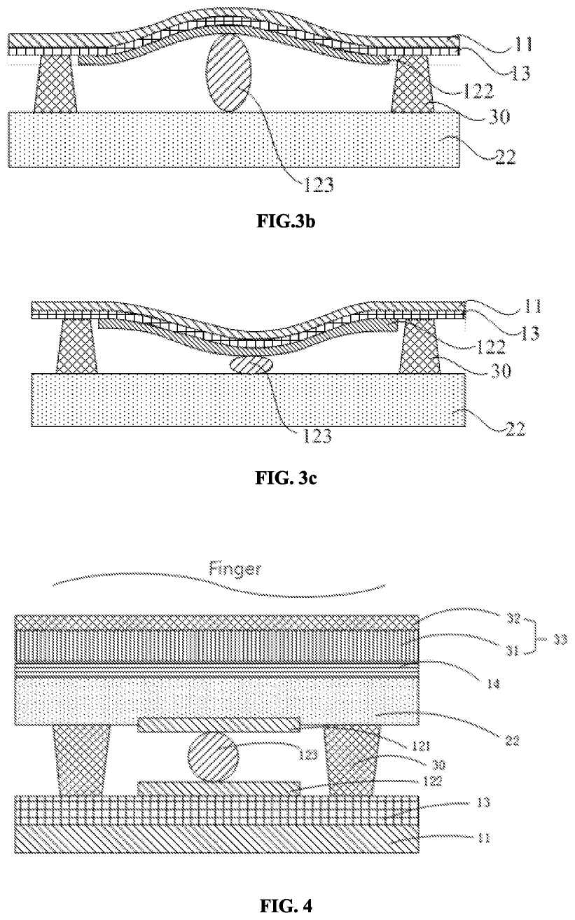

It should be noted that, as shown in FIGS. 3a, 3b and 3c, since the piezoelectric material layer 13 is in contact with the first sub-electrode layers 121 through the first conductive elastic material blocks 123 (the first sub-electrode layers 121 are not shown in the drawings), the first conductive elastic material blocks 123 may be elastically deformed when the piezoelectric material layer 13 is mechanically deformed, so as to allow the piezoelectric material layer 13 to be deformed to a greater degree. When the ultrasonic wave is transmitted, the larger the deformation of the piezoelectric material layer 13 is, the more the ultrasonic wave (i.e., energy) is transmitted, and meanwhile, when the ultrasonic wave is received, the larger the deformation of the piezoelectric material layer 13 is, the more electric charges may be generated, so that the electric signal is more accurate; that is, the degree of deformation of the piezoelectric material layer 13 plays an important role in the emission of the ultrasonic wave and the identification of the reflected ultrasonic wave.

In the ultrasonic module 10 of this embodiment, the first conductive elastic material blocks 123 are provided between the piezoelectric material layer 13 and the first sub-electrode layers 121. Because the first conductive elastic material blocks 123 are elastic, comparing with the ultrasonic module 10 (without the conductive elastic material blocks) in the prior art, the piezoelectric material layer 13 in the ultrasonic module 10 of this embodiment may be deformed to a greater degree in a sufficiently strong electric field, such that more ultrasonic waves may be generated, thereby improving emission rate of the ultrasonic module 10; and such that the piezoelectric material layer 13 may generate more accurate electric signal when receiving the ultrasonic wave, thereby improving the identification performance of the ultrasonic module 10.

In one embodiment, the first conductive elastic material blocks 123 include a plurality of spherical first conductive elastic material blocks 123.

That is, the first conductive elastic material blocks 123 do not fully occupy the area between the piezoelectric material layer 13 and the first sub-electrode layers 121, that is, there is a gap filled with air between the piezoelectric material layer 13 and the first sub-electrode layers 121.

When the ultrasonic wave is transmitted from the material with a large acoustic impedance to the material with a small acoustic impedance, the ultrasonic wave is reflected at an interface between the two materials, so that the ultrasonic wave emitted from the piezoelectric material layer 13 is reflected at an interface between the piezoelectric material layer 13 and the air (an acoustic impedance of the air is smaller than that of the piezoelectric material layer 13); and the amount of the ultrasonic wave emitted from the first electrode unit 11 or the second electrode unit 12 may be increased, and the ultrasonic wave reflected from a finger or other external things is reflected at the interface between the piezoelectric material layer 13 and the air and is absorbed by the piezoelectric material layer 13 again, so that the absorption rate of the piezoelectric material layer 13 for ultrasonic wave is increased, and the identification performance is further improved.

Preferably, as shown in FIG. 2, the second electrode unit 12 further includes a plurality of second sub-electrode layers 122 arranged between the first conductive elastic material blocks 123 and the piezoelectric material layer 13; each of the first sub-electrode layers 121 corresponds to one of the second sub-electrode layers 122 and one of the spherical first conductive elastic material blocks 123.

The second electrode unit 12 includes a plurality of groups separately; each group includes one first sub-electrode layer 121, one second sub-electrode layer 122, and one spherical first conductive elastic material 123. An orthographic projection of the first sub-electrode layer 121 on the piezoelectric material layer 13 and an orthographic projection of the second sub-electrode layer 122 on the piezoelectric material layer 13 are overlapped with each other.

The second sub-electrode layers 122 may enhance the conductivity between the second electrode unit 12 and the piezoelectric material layer 13, so that it is more accurately to convert the mechanical deformation of the piezoelectric material layer 13 to the electric signal; and may enhance the capability of the first electrode unit 11 and the second electrode unit 12 for generating the electric field, so that the mechanical deformation of the piezoelectric material layer 13 is greatly changed, and more ultrasonic waves are generated.

In one embodiment, the orthographic projection of the first sub-electrode layer 121 on the piezoelectric material layer 13 and the orthographic projection of the second sub-electrode layer 122 on the piezoelectric material layer 13 are the same.

In one embodiment, the first electrode unit 11 includes a plurality of third sub-electrode layers 111 and a plurality of second conductive elastic material blocks 110, which are arranged at intervals along a direction parallel to an extension direction of the piezoelectric material layer 13, and the plurality of second conductive elastic material blocks 110 are arranged between the third sub-electrode layers 111 and the piezoelectric material layer 13 (as shown in FIG. 5), each of the plurality of third sub-electrode layers 111 corresponds to a corresponding one of the plurality of second conductive elastic material blocks 110.

That is to say, the second conductive elastic material blocks 110 are arranged between the third sub-electrode layers 111 and the piezoelectric material layer 13.

As such, elastic materials are provided on both sides of the piezoelectric material layer 13, such that in a sufficiently strong electric field, the piezoelectric material layer 13 may be further deformed to a greater degree, such that more ultrasonic waves may be generated, thereby improving emission rate of the ultrasonic module 10; and such that the piezoelectric material layer 13 may generate more accurate electric signals when receiving the ultrasonic wave, thereby improving the identification performance of the ultrasonic module 10.

Specifically, the number of the third sub-electrode layers may be multiple and spaced from each other.

In an embodiment, the ultrasonic module 10 of this embodiment is an ultrasonic fingerprint identification module, and the ultrasonic wave emitted from the ultrasonic module 10 may be reflected by the fingerprint, and the reflectivity of the ultrasonic wave from a valley of the fingerprint is different from that from a ridge of the fingerprint. Accordingly, whether a corresponding position is the valley or the ridge may be determined by analyzing the intensity of the ultrasonic waves at different positions, thereby realizing the fingerprint identification.

In addition, the ultrasonic module 10 of the present embodiment may also be used in other devices or scenes for touch control, space identification, gesture identification, and the like that needs to emit and receive ultrasonic waves.

In another embodiment of the present disclosure, as shown in FIGS. 2, 3a, 3b and 3c, the present embodiment provides an ultrasonic sensor, including: a first substrate 21; a second substrate 22 which is aligned and assembled together with the first substrate 21; the ultrasonic module 10 in the above embodiment is arranged between the first substrate 21 and the second substrate 22, the first substrate 21 is arranged on a side of the first electrode unit 11 distal to the second electrode unit 12, and the second substrate 22 is arranged on a side of the second electrode unit 12 distal to the first electrode unit 11.

Because the conductive elastic material blocks are provided at least at one side of the piezoelectric material layer 13 of the ultrasonic module 10, even if the ultrasonic module 10 is arranged between the rigid first substrate 21 and the rigid second substrate 22, the piezoelectric material layer 13 may be deformed to a large degree, such that more ultrasonic waves may be generated, thereby improving emission rate of the ultrasonic module 10; and such that the piezoelectric material layer 13 may generate more accurate electric signal when receiving the ultrasonic wave, thereby improving the identification performance of the ultrasonic module 10.

In one embodiment, the ultrasonic sensor further includes: supports 30 arranged between the second substrate 22 and the piezoelectric material layer 13, and between the adjacent spherical first conductive elastic material blocks 123, and used for supporting the second substrate 22 and the piezoelectric material layer 13.

That is to say, there are one first sub-electrode layer 121, one second sub-electrode layer 122 and one spherical first conductive elastic material 123 between two adjacent supports 30. The supports 30 are made of a non-conductive and non-elastic material. A cross section of each of the supports 30 may have a circular shape or a square shape, or any achievable shape. In addition, two adjacent supports 30 may form an independent enclosed chamber together with the second substrate 22 and the piezoelectric material layer 13.

The supports 30 support the piezoelectric material layer 13 and the second substrate 22, which may ensure a stable structure of the second electrode unit 12, and a good contractility of the first conductive elastic material blocks 123, thereby prolonging the life of a display screen.

In one embodiment, each first sub-electrode layer 121 and its corresponding second sub-electrode layer 122 correspond to one sub-pixel of the ultrasonic sensor.

Each group of the first sub-electrode layer 121, the second sub-electrode layer 122 and the first conductive elastic material 123 correspond to one sub-pixel, so that touch control, fingerprints or other things may be more accurately identified, and it ensures that the identification performance of the ultrasonic sensor is better.

Specifically, the second substrate 22 is a driving substrate having a pixel driving circuit. The first substrate 21 may be a display substrate. For example, the first substrate 21 includes a driving electrode (an electrode for display) formed of Indium Tin Oxide (ITO), molybdenum (Mo), or the like; the first substrate 21 may also be an insulating glass substrate.

The first electrode unit 11 is electrically coupled to the driving substrate through a conductive connector 40 arranged between the first electrode unit 11 and the second substrate 22. In this way, it unnecessary to individually provide a circuit for supplying voltage to the first electrode unit 11, which simplify the structure of the ultrasonic sensor.

In one embodiment, the present disclosure also provides a display screen, as shown in FIG. 4, including: the ultrasonic sensor described above and a display device 33; and the display device 33 is attached to the ultrasonic sensor.

The display device 33 includes a display panel 31 and a protection screen 32, and the display device 33 is attached to the ultrasonic sensor by a visbreaking glue 14.

In one embodiment, the display screen may be a touch display screen, and further may be a touch display screen capable of implementing fingerprint identification.

Specifically, the display device with the display screen may be any product or component with a display function, such as a liquid crystal display panel, an Organic Light Emitting Diode (OLED) display panel, electronic paper, a mobile phone, a tablet computer, a television, a display, a notebook computer, a digital photo frame, a navigator and the like.

The above ultrasonic module 10 may be integrated with a structure for display. For example, some of the electrodes may be used as the electrodes for display, and the first substrate 21 and the second substrate 22 may be used as two substrates of the display panel. Alternatively, the above ultrasonic module 10 may be hanged outside the display structure. For example, the second substrate 22 is also a substrate of the display panel, and the first substrate 21 is arranged outside the display panel.

It should be noted that, in this document, relational terms such as first and second, and the like are used solely to distinguish one entity or action from another entity or action without necessarily requiring or implying any actual such relationship or order between such entities or actions. Also, the terms “comprises”, “comprising”, or any other variation thereof, are intended to cover a non-exclusive inclusion, such that a process, method, article, or apparatus that includes a list of elements does not include only those elements but may include other elements not expressly listed or inherent to such process, method, article, or apparatus. Without further limitation, an element defined by the phrase “comprising an . . . ” does not exclude the presence of other identical elements in the process, method, article, or apparatus that includes the element.

In accordance with the disclosed embodiments, as described above, these embodiments are not intended to be exhaustive or to limit the invention to the precise embodiments disclosed. Obviously, many modifications and variations are possible in light of the above teaching. The embodiments were chosen and described in order to best explain the principles of the present disclosure and the practical application, to thereby enable a person skilled in the art to best utilize the present disclosure and modified applications based on the present disclosure. The present disclosure is to be limited only by the claims and their full scope and equivalents.

1. An ultrasonic module, comprising:
a piezoelectric material layer;
a first electrode unit on a side of the piezoelectric material layer;
a second electrode unit on a side of the piezoelectric material layer distal to the first electrode unit, wherein
the second electrode unit comprises a plurality of first sub-electrode layers at intervals along a direction parallel to an extending direction of the piezoelectric material layer and a plurality of first conductive elastic material blocks at intervals along the direction parallel to the extending direction of the piezoelectric material layer;
the plurality of first conductive elastic material blocks are between the plurality of first sub-electrode layers and the piezoelectric material layer; and
each of the plurality of first sub-electrode layers corresponds to a corresponding one of the plurality of first conductive elastic material blocks.

2. The ultrasonic module of claim 1, wherein the plurality of first conductive elastic material blocks comprise a plurality of spherical first conductive elastic material blocks.

3. The ultrasonic module of claim 2, wherein the second electrode unit further comprises a plurality of second sub-electrode layers between the plurality of first conductive elastic material blocks and the piezoelectric material layer; and
each of the plurality of first sub-electrode layers corresponds to a corresponding one of the plurality of second sub-electrode layers.

4. The ultrasonic module of claim 3, wherein an orthographic projection of each of the plurality of first sub-electrode layers on the piezoelectric material layer and an orthographic projection of a corresponding one of the plurality of second sub-electrode layers on the piezoelectric material layer are overlapped with each other.

5. The ultrasonic module of claim 1, wherein the first electrode unit comprises a plurality of third sub-electrode layers arranged at intervals along the direction parallel to the extension direction of the piezoelectric material layer and a plurality of second conductive elastic material blocks arranged at intervals along the direction parallel to the extension direction of the piezoelectric material layer; the plurality of second conductive elastic material blocks are between the plurality of third sub-electrode layers and the piezoelectric material layer; each of the third sub-electrode layers corresponds to a corresponding one of the plurality of second conductive elastic material blocks.

6. The ultrasonic module of claim 5, wherein the plurality of second conductive elastic material blocks comprise a plurality of spherical second conductive elastic material blocks.

7. The ultrasonic module of claim 1, wherein the ultrasonic module is an ultrasonic fingerprint identification module.

8. An ultrasonic sensor, comprising:
the ultrasonic module of claim 1;
a first substrate; and
a second substrate, aligned and assembled together with the first substrate;
wherein
the ultrasonic module is between the first substrate and the second substrate, the first substrate is on a side of the first electrode unit distal to the second electrode unit, and the second substrate is on a side of the second electrode unit distal to the first electrode unit.

9. The ultrasonic sensor of claim 8, wherein the ultrasonic module is the ultrasonic module of claim 3, the ultrasonic sensor further comprises:
a plurality of supports arranged at intervals along the direction parallel to the extending direction of the piezoelectric material layer, wherein the plurality of supports are between the second substrate and the piezoelectric material layer and configured to support the second substrate and the piezoelectric material layer; and there are one first sub-electrode layer, one spherical first conductive elastic material block and one second sub-electrode layer between two adjacent supports.

10. The ultrasonic sensor of claim 9, wherein the two adjacent supports form an independent enclosed chamber together with the second substrate and the piezoelectric material layer.

11. The ultrasonic sensor of claim 10, wherein the plurality of supports are made of a non-conductive and non-elastic material, and a cross section of each of the plurality of supports has a circular shape or a square shape.

12. The ultrasonic sensor of claim 8, wherein each of the plurality of first sub-electrode layers and the corresponding second sub-electrode layer together correspond to one sub-pixel of the ultrasonic sensor.

13. The ultrasonic sensor of claim 8, wherein the second substrate is a driving substrate having a pixel driving circuit.

14. The ultrasonic sensor of claim 13, wherein the first electrode unit is electrically coupled to the driving substrate through a conductive connector between the first electrode unit and the second substrate.

15. The ultrasonic sensor of claim 14, wherein the conductive connector is made of a spherical conductive elastic material.

16. A display screen, comprising:
the ultrasonic sensor of claim 8; and
a display device;
wherein the display device is attached to the ultrasonic sensor.

17. The display screen of claim 16, wherein the display device comprises a liquid crystal display panel or an Organic Light Emitting Diode (OLED) display panel.

18. The ultrasonic module of claim 2, wherein the first electrode unit comprises a plurality of third sub-electrode layers arranged at intervals along the direction parallel to the extension direction of the piezoelectric material layer and a plurality of second conductive elastic material blocks arranged at intervals along the direction parallel to the extension direction of the piezoelectric material layer; the plurality of second conductive elastic material blocks are between the plurality of third sub-electrode layers and the piezoelectric material layer; each of the third sub-electrode layers corresponds to a corresponding one of the plurality of second conductive elastic material blocks.

19. The ultrasonic module of claim 3, wherein the first electrode unit comprises a plurality of third sub-electrode layers arranged at intervals along the direction parallel to the extension direction of the piezoelectric material layer and a plurality of second conductive elastic material blocks arranged at intervals along the direction parallel to the extension direction of the piezoelectric material layer; the plurality of second conductive elastic material blocks are between the plurality of third sub-electrode layers and the piezoelectric material layer; each of the third sub-electrode layers corresponds to a corresponding one of the plurality of second conductive elastic material blocks.

20. An ultrasonic sensor, comprising:
the ultrasonic module of claim 2;
a first substrate; and
a second substrate, aligned and assembled together with the first substrate;
wherein
the ultrasonic module is between the first substrate and the second substrate, the first substrate is on a side of the first electrode unit distal to the second electrode unit, and the second substrate is on a side of the second electrode unit distal to the first electrode unit.
